(19) United States
(12) Patent Application Publication
(10) Pub. No.: US 2007/0235786 A1
(43) Pub. Date: Oct. 11, 2007

(54) Storage capacitor and method for producing such a storage capacitor

(75) Inventors: Christian Kapteyn, Dresden (DE); Stephan Kudelka, Dresden (DE)

Correspondence Address: MORRISON & FOERSTER LLP, 1650 TYSONS BOULEVARD, SUITE 400, MCLEAN, VA, 22102, US

(73) Assignee: INFINEON TECHNOLOGIES AG, Munchen (DE)

(21) Appl. No.: 11/399,597

(22) Filed: Apr. 7, 2006

(51) Int. Cl. H01L 31/119; H01L 29/94; H01L 29/76; H01L 27/108

(52) U.S. Cl. 257/301; 257/302

(57) ABSTRACT

A storage capacitor, particularly for use in a storage cell, exhibits two storage electrodes and a dielectric arranged between the two storage electrodes, an intermediate layer essentially consisting of carbon.

### TECHNICAL FIELD OF THE INVENTION

The invention relates to a storage capacitor and to a method for producing such a storage capacitor, particularly for use in a storage cell which is part of a memory. The memory is preferably a dynamic random-access memory (DRAM).

### BACKGROUND OF THE INVENTION

As a rule, memories, especially DRAMs, are implemented as a storage cell matrix on a substrate disk. The storage cells consist of a storage capacitor and a selection transistor. In the case of a read or write process, the storage capacitor is charged or discharged, respectively, with an electrical charge which corresponds to a data unit via the selection transistor. For this purpose, the selection transistor is addressed via a bit or word line with the aid of a peripheral logic having switching transistors.

In the development of the technology, the storage capacitor represents a crucial point. To provide for adequate storage capacity with a small cross sectional area, the storage capacitors are, therefore, implemented three-dimensionally. In this context, trench capacitors and stacked capacitors have been successful as significant embodiments of three-dimensional storage capacitors. In the case of trench capacitors, a trench is etched into the substrate which is filled with a dielectric layer and a first inner storage electrode, a doped area of the substrate around the trench being used as the second outer storage electrode. The selection transistor of the storage cell is constructed adjoining the trench capacitor, preferably as a field-effect transistor, one source/drain electrode of the selection transistor being connected to the one inner storage electrode of the trench capacitor.

Stacked capacitors, in contrast, are formed on the surface of the substrate, a first storage electrode being constructed in the form of a crown which is separated from a second storage electrode via a dielectric layer. The selection transistor of the storage cell is provided underneath the stacked capacitor, preferably in the form of a field-effect transistor, the one source/drain electrode of the selection transistor being connected to the crown-shaped storage electrode of the stacked capacitor.

To provide for rapid access times to the storage capacitor as are desired especially in the case of DRAMs, it is required that the storage electrodes and especially the storage electrode connected to the selection transistor have a high conductivity. The storage electrode connected to the selection transistor is often produced of doped polysilicon, wherein phosphorus is preferably used as dopant which ensures a high conductivity. However, phosphorus diffuses out readily especially at the temperatures used during the DRAM production, meaning that the areas adjoining the storage electrode are inadvertently doped which then leads to unwanted leakage currents. However, the risk of out-diffusion of conductive material out of the storage electrode filling arises not only in the case of polysilicon electrodes doped with phosphorus but also in many other electrode materials used during storage capacitor production.

To prevent out-diffusion of conductive material out of the storage electrode, it is constructed of several layers, as a rule, the inner electrode layer to be protected against out-diffusion being covered with a diffusion barrier on which then a further electrode layer is provided for electrical connection to the surrounding components. The material used for the diffusion barrier in the storage electrode is generally titanium nitride. However, to achieve conformal titanium nitride deposition requires the production of very thick layers. This applies especially to trench capacitors in which the inner electrode connected to the selection transistor of the storage electrode is located in the trench and has a high aspect ratio. To achieve sufficiently good edge coverage in this case, particularly great layer thicknesses are required when titanium nitride is used as diffusion barrier layer. During the application of titanium nitride as diffusion barrier to a polysilicon layer, a poorly conducting boundary area is formed which greatly impairs the conductivity of the storage electrode and can only be prevented by means of elaborate and expensive additional methods and additional layers.

On account of the advancing miniaturization of semiconductor storage cells, additional possibilities are also being sought, in the case of three-dimensional storage capacitors, for simultaneously reducing the area requirement and increasing the capacitor capacitance.

In the case of storage capacitors, material combinations of silicon dioxide and/or silicon nitride are conventionally used as the dielectric intermediate layer. However, in the case of sub-100 nm, the idea is to replace the conventionally used silicon dioxide and/or silicon nitride layers with materials which are distinguished by a higher dielectric constant and thus enable an increased area-specific storage capacity. Binary oxides such as aluminum oxide, tantalum oxide, hafnium oxide, zirconium oxide, oxides of the lanthanum group, aluminum oxide compounds and other individual and mixed oxides are under discussion, in particular, as such so-called high-k dielectrics.

However, many of the high-k dielectrics under consideration can be integrated only with difficulty into the standard process for producing storage capacitors using silicon planar technology. The breakdown strength of many of the high-k dielectrics under consideration is also insufficient for use in DRAM storage capacitors, particularly as far as long-term stability is concerned. In addition, it has been found that, in comparison with the conventional material combinations of silicon dioxide and/or silicon nitride, increased leakage currents which result in a shorter retention time of the charge in the storage capacitor occur in many of the high-k dielectrics under consideration. There is often also material incompatibility between the high-k dielectrics and the adjoining storage electrode layers. This applies, in particular, when the storage electrodes which are adjoined by the dielectric layer exhibit a metal layer for improving conductivity.

When a metal layer is used as the capacitor electrode layer, the problem also exists that, if this layer is applied to a silicon layer, an oxide layer forms in between them and results in an increased contact resistance and thus in a reduction in the conductivity.

### SUMMARY OF THE INVENTION

According to one embodiment of the present invention, there is a storage capacitor, particularly for use in a storage cell, having two storage electrodes, a dielectric arranged between the two storage electrodes, and an intermediate layer which essentially consists of carbon.

According to another embodiment of the present invention, there is a storage capacitor, particularly for use in a storage cell, having two storage electrodes, and a dielectric arranged between the two storage electrodes, the one storage electrode exhibiting a first electrode layer, an intermediate layer arranged on the first electrode layer and essentially consisting of carbon, and a second electrode layer arranged on the intermediate layer.

According to still another embodiment of the present invention, there is a storage capacitor, particularly for use in a storage cell, having a trench being formed in a substrate, a first storage electrode being formed as outer electrode in the substrate around the trench in a lower trench area, a dielectric being formed on the trench wall in the lower trench area, an insulation layer being formed adjoining the dielectric on the trench wall in an upper trench area, and a second storage electrode being formed as inner electrode in the trench, the second storage electrode comprising a first electrode layer covering the dielectric, an intermediate layer arranged on the first electrode layer adjoining the insulation layer and essentially consisting of carbon and a second electrode layer arranged on the intermediate layer essentially filling the trench.

According to yet another embodiment of the present invention, there is a DRAM memory chip with DRAM storage cells which in each case exhibits a storage capacitor and a selection transistor. The storage capacitor comprises a first storage electrode being formed as outer electrode in a substrate around a trench in a lower trench area, a dielectric being formed on the trench wall in the lower trench area, an insulation layer being formed adjoining the dielectric on the trench wall in an upper trench area, and a second storage electrode being formed as inner electrode in the trench, the second storage electrode comprising a first electrode layer covering the dielectric, an intermediate layer arranged on the first electrode layer adjoining the insulation layer and a second electrode layer arranged on the intermediate layer essentially filling the trench, the intermediate layer essentially consisting of carbon. The selection transistor exhibits a first and a second source/drain electrode and a gate electrode and the one source/drain electrode of the selection transistor being electrically conductively connected to the inner electrode of the storage capacitor.

According to another embodiment of the present invention, there is a storage capacitor, particularly for use in a storage cell, having two storage electrodes, the one storage electrode exhibiting a metal layer, a dielectric arranged between the two storage electrodes, and an intermediate layer essentially consisting of carbon and being provided between the metal layer and a substrate.

According to still another embodiment of the present invention, there is a storage capacitor, particularly for use in a storage cell, having two storage electrodes, the one storage electrode exhibiting a metal layer, a dielectric arranged between the two storage electrodes, and an intermediate layer which essentially consists of carbon being provided between the metal layer and the dielectric.

According to a yet another embodiment of the present invention, there is a method for producing a storage capacitor, particularly for use in a storage cell, including the forming of two storage electrodes, a dielectric arranged between the two storage electrodes and an intermediate layer which essentially consists of carbon.

### BRIEF DESCRIPTION OF THE DRAWINGS

The present invention is described below in more detail with reference to the exemplary embodiments and drawings, in which:

FIG. 1 shows a circuit diagram of a DRAM cell.

FIG. 2 shows a diagrammatic cross section through a DRAM cell with a first embodiment of a storage capacitor according to the invention.

FIGS. 3A to 3F show a first embodiment of a method according to the invention for producing a storage capacitor.

FIG. 4 shows a diagrammatic cross section through a DRAM cell with a second embodiment of a storage capacitor according to the invention.

FIGS. 5A to 5F show a second embodiment of a method according to the invention for producing a storage capacitor.

FIG. 6 shows a diagrammatic cross section through a DRAM cell with a third embodiment of a storage capacitor according to the invention.

FIGS. 7A to 7F show a third embodiment of a method according to the invention for producing a storage capacitor.

### DETAILED DESCRIPTION OF THE INVENTION

The invention will be explained with reference to the production of storage capacitors during a process sequence for forming DRAM storage cells on a silicon base. However, the storage capacitors according to the invention can also be used in other highly integrated circuits in which such storage capacitors are needed. Furthermore, the possibility also exists to construct the storage capacitors in other substrates instead of in silicon.

The storage capacitors are preferably constructed with the aid of planar technology which consists of a sequence of individual processes in each case acting over the entire area on the disk surface, a local change in the substrate being performed deliberately by suitable masking steps. During the DRAM production, a multiplicity of cells with corresponding storage capacitors are simultaneously formed. In the text which follows, however, the invention will be essentially explained with reference to a single storage capacitor.

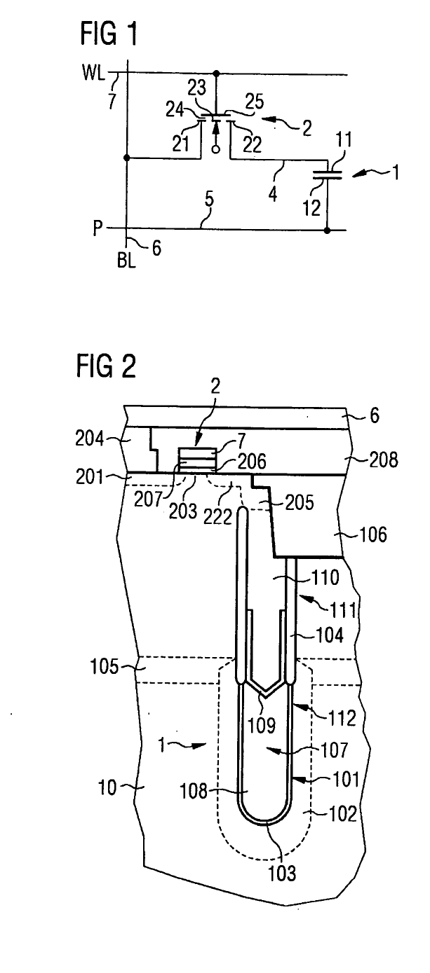

In DRAM memories, one-transistor cells are predominantly used, the circuit diagram of which is shown in FIG. 1. These one-transistor cells consist of a storage capacitor 1 and a selection transistor 2. The selection transistor 2 is preferably designed as field-effect transistor and has a first source/drain electrode 21 and a second source/drain electrode 22, between which an active area 23 is arranged in which a current-conducting channel can form between the first source/drain electrode 21 and the second source/drain electrode 22. Over the active area 23, an insulator layer 24 and a gate electrode 25 are arranged which act like a plate capacitor by means of which the charge density can be influenced in the active area 23.

The second source/drain electrode 22 of the selection transistor 2 is connected via an electrical connection 4, the so-called “buried strap”, to a first storage electrode 11 of the storage capacitor 1. A second storage electrode 12 of the storage capacitor 1, in turn, is connected to a conducting connection 5 which is preferably common to all storage capacitors of the DRAM memory. The first source/drain electrode 21 of the selection transistor 2 is also connected to a bit line 6 in order to be able to read or write the information stored in the storage capacitor in the form of charges. The write or read process is controlled via a word line 7 which is connected to the gate electrode 25 of the selection transistor 2 in order to produce a current-conducting channel in the active area 23 between the first source/drain electrode 21 and the second source/drain electrode 22 by applying a voltage.

As a rule, storage capacitors having a three-dimensional structure are used in DRAM memories which enables the DRAM cell area to be significantly reduced and, at the same time, ensures simple production in planar technology. Using three-dimensional storage capacitors, a capacitance of 25 to 50 fF can be achieved, in particular, which is needed for obtaining an adequate read signal for the DRAM cells.

A further decisive factor for using storage capacitors in DRAM memories is a rapid access capability to the memory content. This requires that storage electrodes have high conductivity.

The storage electrode connected to the selection transistor often has a layer structure which is derived from the special DRAM production conditions. Between the individual electrode layers, intermediate layers are provided which serve as diffusion barrier in order to prevent out-diffusion of conductive material out of the layer lying underneath, e.g. the out-diffusion of phosphorus when phosphorus-doped polysilicon layers are used. This is because such a diffusion of conductive material creates the risk of doping unwanted areas which in turn impairs the electrical characteristics of the storage capacitor or of the storage cell, respectively. Thus, leakage currents can increasingly occur over the areas contaminated by out-diffusion.

In order to achieve improved conductivity of the storage electrodes, a metal layer is furthermore used in the storage electrodes in addition to, or instead of, the polysilicon. However, when applying such a metal layer, there is the risk of a high contact resistance being established in the boundary area. This applies, in particular, when the metal layer is deposited on a silicon substrate using the conventional CVD or ALD methods. This is because a silicon oxide boundary area layer having a high resistance then generally forms. This may be disruptive, in particular, when the storage capacitor is operated at a high frequency since a high resistance which is connected in series and impairs the storage capacity is then produced between the silicon substrate and the metal electrode.

In order to increase the capacitor capacitance, so-called high-k dielectrics which are distinguished by a higher dielectric constant and thus an increased area-specific storage capacity are also increasingly being used instead of the dielectric layer which is usually produced from silicon oxide or silicon nitride. Binary oxides, aluminum oxide, tantalum oxide, hafnium oxide, zirconium oxide, oxides of the lanthanum group, aluminum oxide compounds and other individual and mixed oxides are under discussion, in particular, as such high-k dielectrics. However, the materials under consideration can be integrated only with difficulty into the standard process for producing storage capacitors using silicon planar technology. In particular, many of these high-k dielectrics are incompatible, in terms of material, with a storage electrode formed as a metal layer.

According to the invention, a layer essentially consisting of carbon is therefore used, in critical boundary areas, as intermediate layer in the storage capacitor. Carbon is distinguished by high conductivity. In addition, carbon deposition can be performed simply, easily and cleanly, particularly with the aid of a pyrolytic deposition method, as a result of which thin carbon layers can be formed. However, carbon can also be removed again easily and controllably out of unwanted areas, e.g. by oxidation at 850° C. in an N₂/O₂ atmosphere, and can thus be integrated well into the standard DRAM production process. Furthermore, carbon is distinguished by good edge coverage, particularly also when applied in trenches with a high aspect ratio as occurs in the case of trench capacitors. Carbon layers, particularly pure carbon layers, are excellently suited as diffusion barrier on a doped polysilicon layer since an ideal boundary surface without boundary surface defects or disturbing intermediate depositions is produced.

In the text which follows, the construction of a first embodiment of a storage capacitor according to the invention having an intermediate layer essentially consisting of carbon in a storage electrode is represented with the example of a trench capacitor. However, the storage capacitor can also have a different structure, particularly another three-dimensional structure, e.g. a stacked structure.

FIG. 2 shows an embodiment of a DRAM cell with such a storage capacitor 1 according to the invention in the form of a trench capacitor. The trench capacitor 1 is formed in a preferably monocrystalline silicon substrate 10. The substrate is preferably weakly p-(p⁻)-doped, e.g. with boron (B). In the silicon substrate 10, a trench 101 is constructed which is composed of an upper trench area 111 and a lower trench area 112. Around the lower trench area 112, a highly n-(n⁺)-doped layer 102 is formed, for example by arsenic doping. This n⁺-doped layer 102 represents the outer capacitor electrode of the trench capacitor 1 as “buried plate”.

In the lower trench area 112, a storage dielectric 103 is also provided on the trench wall. The storage dielectric 103 consists of a thin layer or also a thin layer stack with high dielectric constant, e.g. of oxide-nitride-oxide or a high-k material.

In the upper trench area 111, an insulation layer 104 is provided on the trench wall adjoining the dielectric layer 102. This insulation layer 104 prevents a parasitic transistor being produced along the trench 101 between the selection transistor 2 and the n⁺-doped layer 102, which would cause an unwanted leakage current which would significantly shorten the retention time of the charges in the trench capacitor and thus increase the required refresh frequency of the DRAM cell in unwanted manner. The insulation layer 104 is preferably formed by an oxide or nitride.

In the silicon substrate 10, an n-doped well 105 is also provided which serves as conducting connection of the n⁺-doped layer 102 to the n⁺-doped layers of the further DRAM cells. An insulation trench 106 (STI insulation) is formed to provide insulation between the individual DRAM cells.

The trench 101 is filled with a conductive layer sequence 107 which forms the inner capacitor electrode of the trench capacitor. The layer sequence 107 of the inner capacitor electrode exhibits a first filling layer 108 which completely covers the storage dielectric 103 on the trench wall. The first filling layer 108 preferably consists of phosphorus-doped polysilicon which ensures high conductivity of the filling layer.

The first filling layer 108 of the inner capacitor electrode 107 in turn is covered by a thin, preferably 1 to 50 nm-thick intermediate layer 109 which adjoins the insulation layer 104 and covers the latter, as shown in FIG. 2, preferably the area adjoining the dielectric layer 103. The intermediate layer 109 consists of carbon, preferably of pure carbon, and has a high conductivity of approx. 1 mΩcm. At the same time, the carbon intermediate layer 109 prevents out-diffusion of material out of the first filling layer 108 lying underneath, particularly when this first filling layer 108 consists of phosphorus-doped polysilicon. In addition, the carbon layer 109 forms a perfect boundary area to the first filling layer 108 lying underneath, so that a highly conductive interface is produced between these layers.

On the carbon intermediate layer 109, a further electrode layer 110 is arranged which then essentially completely fills the trench 101. The second electrode layer 110 of the inner capacitor electrode is preferably produced of arsenic-doped polysilicon. Here, too, an ideal boundary area to the carbon intermediate layer 108 lying underneath is formed, as a result of which a highly conductive interface is produced.

As an alternative to an inner capacitor electrode consisting of a polysilicon filling with a carbon intermediate layer, other conductive materials which are separated by a carbon intermediate layer can also be used. Instead of the arsenic and phosphorus dopants in the two polysilicon electrode layers, other dopants can also be used. Furthermore, the possibility exists to apply an additional metal layer, preferably directly on the dielectric 103, underneath the first phosphorus-doped polysilicon filling layer, for increasing the storage capacity and conductivity. Such a metal layer can also be provided between the dielectric layer 103 and the outer capacitor electrode 102 for improving the capacitor capacitance.

In the embodiment shown in FIG. 2, the selection transistor 2 of the DRAM cell exhibits two diffusion areas 201, 202 which are created by implanting n-type doping atoms in the silicon substrate 10 and separated by a channel 203. The first diffusion area 201 is used as first source/drain electrode 21 of the selection transistor 2 and is connected to the bit line 6 by a contact layer 204. The second diffusion area 202 is used as second source/drain electrode 22 of the selection transistor 2 and is connected by a capacitor connection layer 205, which forms the “buried strap”, to the upper filling layer 110 which is part of the inner storage electrode 12 of the trench capacitor 1.

The channel 203 between the first diffusion area 201 and the second diffusion area 202 is separated from a gate electrode layer 207, which is part of the word line 7, by a dielectric layer 206. The gate electrode layer 207 and the word line 7 are separated from the bit line 6 and the contact layer 204 by an insulation layer 208.

A read and write process in the DRAM cell is controlled by the word line 7 which is connected to the gate electrode layer 207 of the selection transistor 2 in order to produce a current conduction in the channel 203 between the first and the second diffusion areas 201, 202 by applying a voltage so that information in the form of charges can be written into and read out of the inner storage electrode 107 in the trench 101 of the trench capacitor 1 via the connecting layer 205.

The embodiment of the storage capacitor according to the invention with a carbon intermediate layer in a storage electrode can be integrated into the familiar DRAM process sequences in a simple manner. In the further text, the production of a trench capacitor pair during a standard DRAM process sequence is shown. However, it is possible to construct the storage capacitor with a carbon intermediate layer in a storage electrode by means of other familiar DRAM process sequences.

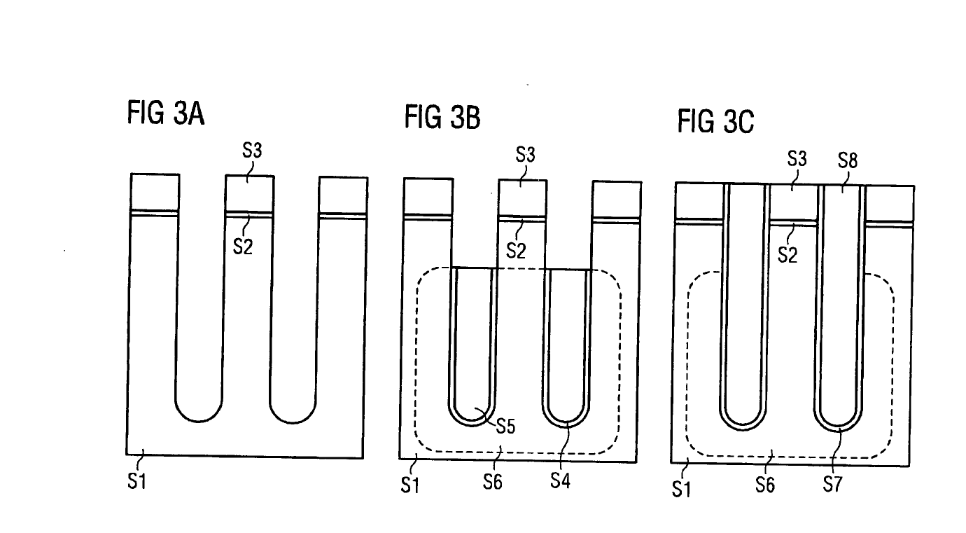

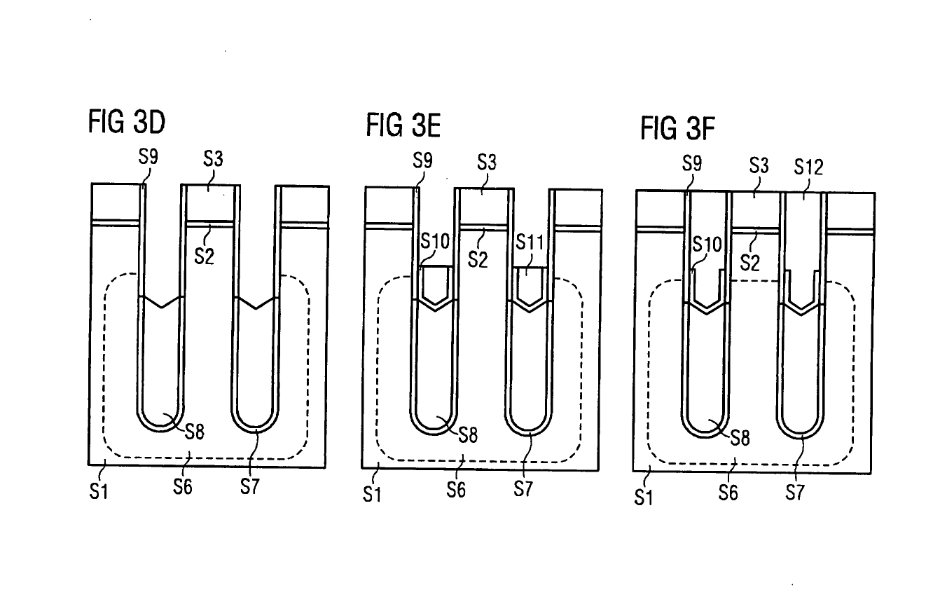

FIGS. 3A to 3F in each case diagrammatically show cross sections of successive process stages in the construction of storage capacitors during a standard DRAM process.

As shown in FIG. 3A, the trenches for the trench capacitors are formed in a p⁻-doped silicon substrate S1 in a first process step. For this purpose, an oxide layer S2 and a nitride layer S3 are successively created on the silicon surface. Following this, the areas of the trench capacitors are defined in familiar manner on the silicon surface by means of a mask layer and then trenches with a depth of approx. 10 μm are created by means of a first anisotropic etching. FIG. 3A shows a cross section through the silicon disk after the trench etching.

In a next process step, the outer capacitor electrode, which is constructed as buried plate, is then produced. For this purpose, a doping layer S4, e.g. arsenic glass, is deposited on the trench wall and then the trenches are filled with photoresist S5 up to the lower trench section around which the buried plate is to be formed. Following this, the doping layer S4 is removed again in the area not covered by photoresist and dopant, arsenic in the case of an arsenic glass layer, is diffused out into the surrounding silicon substrate S1 by baking so that an n⁺-doped layer S6 is produced around the lower area of the trench. FIG. 3B shows a cross section through the storage capacitors after this process step.

Following this, the photoresist S5 and the remaining doping layer S4 are removed again out of the trenches and the dielectric S4 is produced in a next step. For this purpose, e.g. an ONO deposition is performed. Following this, the trenches are filled with a first conducting layer S8, preferably a phosphorus-doped polysilicon which is chemically-mechanically polished back so that the filling remains limited to the trenches. FIG. 3C shows a cross section through the silicon disk after this process step.

In a further process sequence, the polysilicon filling is then etched back into the trenches until below the area at which the buried plate S6 begins. Following this, the dielectric layer S7 is then removed from the exposed trench wall and an insulation layer S9 is produced on these exposed trench sections, preferably a silicon oxide layer. FIG. 3D shows a cross section through the silicon disk after the formation of the so-called collar layer.

In a further process step, the carbon-containing intermediate layer S10 is then produced. For this purpose, a thin carbon layer with a thickness of preferably 1 to 50 nm is pyrolytically deposited on the exposed surface and subsequently the trenches are then filled up with photoresist S11. This photoresist filling S11 is then etched back into the trenches to the extent that the carbon layer S11 is exposed in the upper trench area. The carbon layer S11 is then removed in the exposed wall areas, e.g. by oxidation at a temperature of 850° C. in an N₂/O₂ atmosphere. FIG. 3E shows a cross section through the silicon disk after this process step.

Following this, the remaining photoresist S11 is then removed again out of the trenches and the trenches are filled with a further conductive material, preferably arsenic-doped polysilicon S12 in order to complete by this means the inner storage electrode of the trench capacitor consisting of the layer sequence phosphorus-doped polysilicon S8, carbon S10 and arsenic-doped polysilicon S12. FIG. 3F shows a cross section through the silicon disk after the chemical-mechanical polishing of the arsenic-doped polysilicon layer S12.

To complete the storage cell as part of the standard DRAM process, selection transistors adjoining the trench capacitors are then produced, a connection between the arsenic-doped polysilicon filling S12 in the trench, which is part of the inner storage electrode, and a diffusion area of the selection transistor being produced via the so-called “buried strap”.

The method shown produces in a simple manner a carbon-containing intermediate layer between two electrode layers of the one storage electrode, the carbon layer being distinguished by a perfect boundary surface with the two electrode layers and a high conductivity whilst simultaneously preventing diffusion of material through the intermediate layer. The method shown is not restricted to a DRAM production process but can be used for forming other known components with storage capacitors.

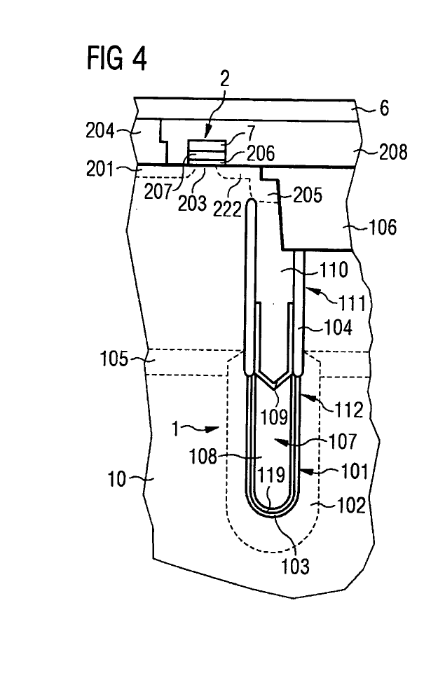

In the text which follows, the construction of a second embodiment of a storage capacitor according to the invention having an intermediate layer essentially consisting of carbon between a storage electrode having a metal layer and the adjoining dielectric is explained using the example of a trench capacitor. However, the storage capacitor can also again have another structure, particularly another three-dimensional structure, e.g. a stacked structure. FIG. 4 shows an embodiment of a DRAM cell with such a storage capacitor according to the invention in the form of a trench capacitor. In this case, the trench capacitor shown in FIG. 4 essentially corresponds to the trench capacitor shown in FIG. 2. The same layers and components are therefore also provided with the same reference symbols.

However, in contrast to the embodiment shown in FIG. 2, the conductive layer sequence 107 in the trench 101 according to the embodiment shown in FIG. 4 is not formed directly on the dielectric layer 103 but rather is formed separately by means of a thin intermediate layer 119 which preferably has a thickness of 0.5 to 10 nm. This intermediate layer 119 covers the dielectric layer 103 and consists of carbon, preferably of pure carbon having a high conductivity of approximately 1 mΩcm. In this case, the dielectric layer 103 preferably consists of a high-k dielectric, preferred materials being binary oxides such as aluminum oxide (Al₂O₃), tantalum oxide (Ta₂O₅), hafnium oxide (HfO₂) and zirconium oxide (ZrO₂). Lanthanum oxide (La₂O₃) or yttrium oxide (Y₃O₃) may also be used. Aluminum oxide compounds are also suitable as high-k dielectrics. In this case, compounds containing hafnium, zirconium or lanthanum, for example Hf—Al—O, Zr—Al—O or La—Al—O, are particularly suitable. Furthermore, high-k dielectrics may also be produced from silicate compounds, for example Hf—Si—O, Zr—Si—O, La—Si—O or Y—I—O. Moreover, other individual or mixed oxides, for example nitrides from transition group four or five and from main group three or four, are suitable as high-k dielectrics.

A metal layer, for example a titanium nitride layer, is preferably used as the first filling layer 108 of the inner capacitor electrode 107. The carbon layer 119 affords a perfect boundary area between the dielectric layer 103 and the first filling layer 108, with the result that readily conductive boundary areas are produced between these layers. Moreover, the carbon layer ensures high thermal stability, particularly when the filling layer 108 is a metal layer.

As an alternative to the embodiment shown, the inner capacitor electrode 107 may also consist entirely of a metal layer, with the result that it is possible to dispense with the multilayer construction shown in FIG. 4. In the case of a multilayer construction of the inner capacitor electrode 107, it is also possible to dispense with the carbon intermediate layer 109 which is provided between the electrode layers.

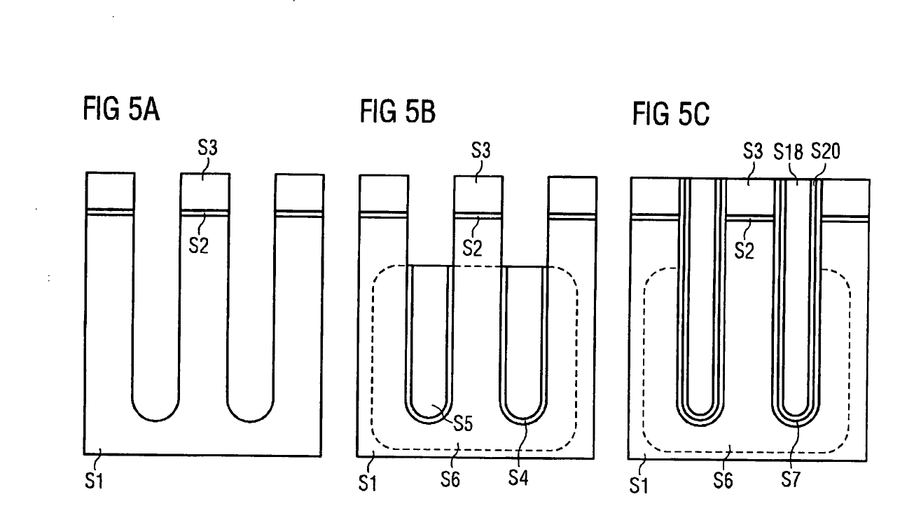

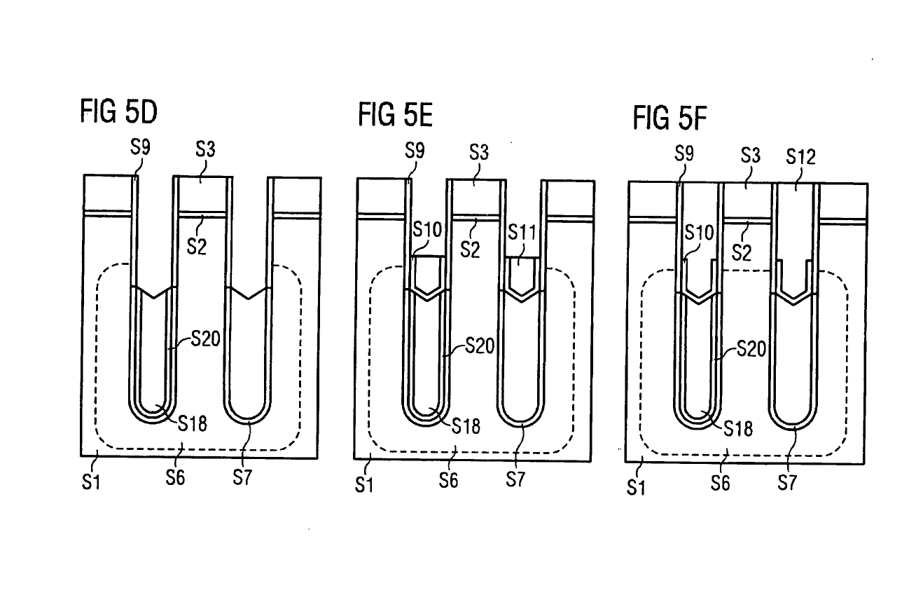

FIGS. 5A to 5F show the method for producing a trench capacitor pair with a carbon intermediate layer between the dielectric layer and the inner capacitor electrode. In this case, the method sequence largely corresponds to the method sequence described with reference to FIGS. 3A to 3F, with the result that the same layers are provided with the same reference symbols.

However, in contrast to the method sequence described with reference to FIGS. 3A to 3F, a further thin carbon-containing intermediate layer S20 is applied after application of the dielectric layer S7 which is preferably formed from a high-k dielectric. The trenches are subsequently filled with a first conductive layer S18 which is preferably a metal layer, for example a titanium nitride layer. FIG. 5C shows the cross section through the silicon disk after this process step.

The further process sequence corresponds to the process sequence described with reference to FIGS. 3A to 3F but, as shown in FIG. 5D, in order to apply the insulation layer S9, the trench wall is exposed by also etching back, in addition to the dielectric layer S7 and the filling layer S8, the carbon-containing intermediate layer S20 which is arranged between them.

As a result of the procedure according to the invention, it is easily possible to generate a carbon-containing intermediate layer between the dielectric layer and an electrode layer of the storage electrode. The carbon layer provides a perfect boundary area between the layers and thus high conductivity. At the same time, material is prevented from diffusing between the layers. The carbon layer also makes it possible to use a high-k dielectric as the dielectric and to apply a metal layer, as an electrode layer, to said dielectric.

In the text which follows, the construction of a third embodiment of the storage capacitor according to the invention with an intermediate layer essentially consisting of carbon between the substrate and a storage electrode is again described using the example of a trench capacitor. In this case too, other structures, in particular other three-dimensional structures such as stacked structures, may be used.

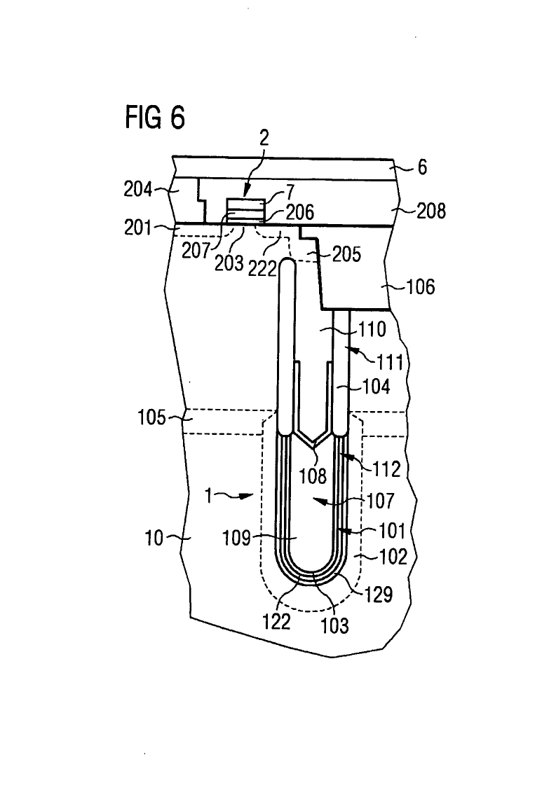

In this case, the embodiment shown in FIG. 6 largely corresponds to the embodiment shown in FIG. 2, with the result that the same layers and components are provided with the same reference symbols. However, in contrast to the embodiment shown in FIG. 2, the outer capacitor electrode of the trench capacitor exhibits, in addition to the n⁺-doped layer 102 which constitutes the buried plate, a metal layer 122, for example a titanium nitride layer, which is applied to the dielectric layer 103 which is again preferably a high-k dielectric. A further thin intermediate layer which preferably has a thickness of 0.5 to 10 nm and consists of carbon, preferably of pure carbon, is provided between the n⁺-doped layer 102 of the outer capacitor electrode and the metal layer 122. This carbon intermediate layer 129 provides an ideal boundary area between the metal layer 122 and the n⁺-doped layer 102 and thus provides a low contact resistance.

In particular, as a result of the carbon intermediate layer 129, the formation of a disruptive oxide layer between the metal layer and the silicon, which usually results when applying metal layers to silicon, is also avoided.

As an alternative to the embodiment shown in FIG. 6, it is also possible to dispense with the n⁺-doped layer 102 of the outer capacitor electrode and to directly connect the metal layer 122 to the silicon substrate via the carbon intermediate layer 129. Furthermore, as shown in the embodiment shown in FIG. 4, it is also possible for the inner capacitor electrode to exhibit a metal layer which is again preferably separated from the dielectric layer by means of a carbon intermediate layer, as shown in FIG. 4.

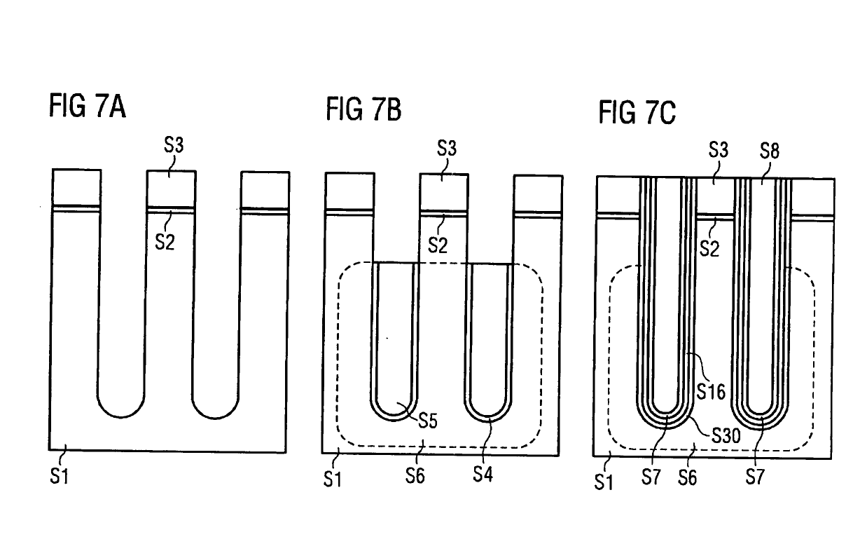

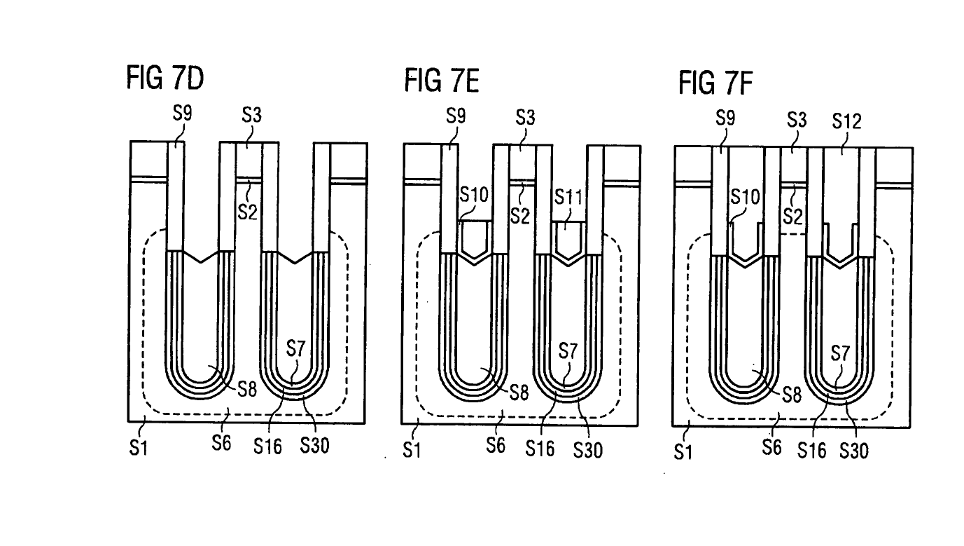

The configuration of the storage capacitor according to the invention with a carbon intermediate layer between the substrate and the one storage electrode can, in turn, be easily integrated into the known DRAM process sequences. FIGS. 7A to 7F show one possible process sequence. This process sequence largely corresponds to the process sequence shown in FIGS. 3A to 3F. The same layers are therefore also provided with the same reference symbols again.

However, the process sequence for forming the third embodiment differs from the process sequence shown using FIGS. 3A to 3F by the process step shown in FIG. 7C. According to the process map shown in FIG. 7C, a thin carbon layer S30 which preferably has a thickness of 0.5 to 10 nm is deposited before the dielectric layer S7 is applied. A thin metal layer S16 is subsequently applied and the dielectric layer S7 is then deposited. Finally, the trenches are filled with the filling layer S8.

In order to form the insulation layer S108, as shown in FIG. 7D, the entire applied layer sequence comprising the carbon layer S30, the metal layer S16, the dielectric layer S7 and the filling layer S8 is then etched back in order to expose the upper trench wall and to generate a silicon oxide layer here. The further process sequence then corresponds to the process sequence shown in FIGS. 3A to 3F.

The procedure described makes it possible to easily generate a carbon-containing intermediate layer between the substrate and a storage electrode of the storage capacitor, the carbon layer generating a perfect boundary area and, at the same time, preventing material from diffusing between the layers.

It is furthermore within the scope of the invention to modify the stated dimensions and concentrations, materials and processes in a suitable manner beyond the above-mentioned exemplary embodiments in order to produce the storage capacitor according to the invention with carbon-containing intermediate layer. In particular, all known process sequences for forming storage capacitors as part of DRAM production processes can be utilized.

It is furthermore possible to make the type of conductivity of the doped areas of the component structure complementary. Furthermore, the materials specified for forming the various layers can be replaced by other materials known in this connection. In the layer sequence shown, other layers, not shown, can also be inserted. Furthermore, the mask sequences in the structuring processes shown can be modified in a suitable manner without departing from the area of the invention.

The invention provides a storage capacitor and a method for producing it, which capacitor and method result in improved electrical and mechanical properties of the storage capacitor.

According to the invention, a storage capacitor, particularly for use in a storage cell, exhibits two storage electrodes and a dielectric arranged between the two storage electrodes, an intermediate layer essentially consisting of carbon.

Using carbon as an intermediate layer provides an excellent diffusion barrier against out-diffusion of material out of the layer which adjoins the intermediate layer. In addition, the application of carbon is a simple, inexpensive and clean process in which an almost perfect boundary area is formed on the electrode layer lying underneath, which guarantees high conductivity, good long-term stability and high capacitance of the storage capacitor. In addition, carbon can also be produced with high conformity as a thin film with very good edge coverage and can also be removed very easily and in a controllably masked manner, e.g. by oxidation at 850° C. in an N₂/O₂ atmosphere.

According to the invention, the one storage electrode exhibits a first electrode layer, the intermediate layer arranged on the first electrode layer and a second electrode layer arranged on the intermediate layer, the intermediate layer essentially being formed of carbon.

The intermediate layer (which consists of carbon) in the storage electrode produces an excellent diffusion barrier against out-diffusion of material out of the adjoining electrode layers. The application of carbon also provides an almost perfect boundary area with respect to the adjoining electrode layers, which guarantees high conductivity of the storage electrode exhibiting the intermediate layer.

According to the invention, the intermediate layer is formed as a pure carbon layer, preferably with a thickness of 1 to 50 nm. Furthermore, the first electrode layer is preferably to be produced of polysilicon doped with phosphorus and the second electrode layer is to be produced of polysilicon doped with arsenic. With such a storage electrode design, especially high conductivity is achieved whilst simultaneously preventing out-diffusion of the dopants, particularly of phosphorus.

Furthermore, the use of the storage electrode with the carbon intermediate layer as inner electrode in a trench capacitor is preferred since carbon can be constructed as a thin layer with conformity with good edge coverage even with a high aspect ratio in the trench. The carbon deposition preferably takes place pyrolytically as a result of which a layer with high conformity can be inexpensively produced.

According to the invention, the one storage electrode exhibits a metal layer, the intermediate layer which essentially consists of carbon being formed between the metal layer and a substrate. The carbon intermediate layer between the metal layer and the substrate reliably prevents out-diffusion of material out of the metal layer and provides a perfect boundary area, thus resulting in a low contact resistance and thus high conductivity.

In this case, use is preferably made of a pure carbon layer having a thickness which is preferably in the range from 0.5 to 10 nm. In the context of a storage capacitor, such a configuration makes it possible to apply a metal electrode to a substrate, particularly a silicon substrate. In this case, the carbon layer ensures that no disruptive oxide is produced between the silicon substrate and the metal layer and that a low contact resistance is thus produced. A high resistance that occurs in series between the metal layer and the substrate would result, particularly at high frequencies, in the capacitance of the storage capacitor being considerably reduced when reading in and out.

According to the invention, the one storage electrode exhibits a metal layer, the intermediate layer which essentially consists of carbon being provided between the metal layer and the dielectric.

The carbon layer as an intermediate layer between the dielectric and the metal electrode provides an excellent diffusion barrier, the good electrical properties of the carbon resulting in high conductivity of the metal electrode. Moreover, the carbon intermediate layer improves the long-term stability of the storage capacitor. This applies, in particular, when the intermediate layer is a pure carbon layer, preferably having a thickness of 0.5 to 10 nm.

The carbon intermediate layer also makes it possible to provide a storage capacitor having a so-called MIS (metal-insulator-silicon) construction in which the insulator layer consists of a high-k dielectric.

What is claimed is:

1. A storage capacitor for use in a storage cell, comprising:
two storage electrodes;
a dielectric arranged between the two storage electrodes; and
an intermediate layer which essentially consists of carbon.

2. The storage capacitor as claimed in claim 1, wherein the intermediate layer is a pure carbon layer.

3. A storage capacitor for use in a storage cell, comprising:
two storage electrodes;
a dielectric arranged between the two storage electrodes, one storage electrode exhibiting a first electrode layer;
an intermediate layer arranged on the first electrode layer and essentially consisting of carbon; and
a second electrode layer arranged on the intermediate layer.

4. The storage capacitor as claimed in claim 3, wherein the intermediate layer is a pure carbon layer.

5. The storage capacitor as claimed in claim 3, wherein the intermediate layer is 1 to 50 nm thick.

6. The storage capacitor as claimed in claim 3, wherein the first electrode layer consists of phosphorus-doped polysilicon.

7. The storage capacitor as claimed in claim 3, wherein the second electrode layer consists of arsenic-doped polysilicon.

8. A storage capacitor for use in a storage cell, comprising:
a trench being formed in a substrate;
a first storage electrode formed as an outer electrode in the substrate around the trench in a lower trench area;
a dielectric formed on the trench wall in the lower trench area;
an insulation layer formed adjoining the dielectric on the trench wall in an upper trench area; and
a second storage electrode formed as an inner electrode in the trench, the second storage electrode comprising a first electrode layer covering the dielectric, an intermediate layer arranged on the first electrode layer adjoining the insulation layer and essentially consisting of carbon and a second electrode layer arranged on the intermediate layer essentially filling the trench.

9. The storage capacitor as claimed in claim 8, wherein the intermediate layer is a pure carbon layer.

10. The storage capacitor as claimed in claim 8, wherein the intermediate layer is 1 to 50 nm thick.

11. A DRAM memory chip with DRAM storage cells which in each case exhibit a storage capacitor and a selection transistor, the storage capacitor comprising:
a first storage electrode formed as an outer electrode in a substrate around a trench in a lower trench area;
a dielectric formed on the trench wall in the lower trench area;
an insulation layer formed adjoining the dielectric on the trench wall in an upper trench area; and
a second storage electrode formed as inner electrode in the trench,
the second storage electrode comprising a first electrode layer covering the dielectric, an
intermediate layer arranged on the first electrode layer adjoining the insulation layer and a second electrode layer arranged on the intermediate layer essentially filling the trench,
the intermediate layer essentially consisting of carbon, and
the selection transistor exhibiting a first and a second source/drain electrode and a gate electrode and the one source/drain electrode of the selection transistor being electrically conductively connected to the inner electrode of the storage capacitor.

12. The DRAM memory chip as claimed in claim 11, wherein the intermediate layer is a pure carbon layer.

13. A storage capacitor for use in a storage cell, comprising:
two storage electrodes, one storage electrode exhibiting a metal layer;
a dielectric arranged between the two storage electrodes; and
an intermediate layer essentially consisting of carbon and being provided between the metal layer and a substrate.

14. The storage capacitor as claimed in claim 13, wherein the intermediate layer is a pure carbon layer.

15. The storage capacitor as claimed in claim 13, wherein the intermediate layer is 0.5 to 10 nm thick.

16. The storage capacitor as claimed in claim 13, wherein the substrate is a silicon substrate.

17. A storage capacitor for use in a storage cell, comprising:
two storage electrodes, one storage electrode exhibiting a metal layer;
a dielectric arranged between the two storage electrodes; and
an intermediate layer which essentially consists of carbon being provided between the metal layer and the dielectric.

18. The storage capacitor as claimed in claim 17, wherein the intermediate layer is a pure carbon layer.

19. The storage capacitor as claimed in claim 17, wherein the intermediate layer is 0.5 to 10 nm thick.

20. The storage capacitor as claimed in claim 17, wherein the dielectric is a high-k dielectric.

21. A method for producing a storage capacitor for use in a storage cell, comprising:
providing two storage electrodes;
arranging a dielectric arranged between the two storage electrodes; and
forming an intermediate layer which essentially consists of carbon.

22. The method as claimed in claim 21, wherein one storage electrode is formed with a first electrode layer, the intermediate layer arranged on the first electrode layer and essentially consisting of carbon and a second electrode layer arranged on the intermediate layer.

23. The method as claimed in claim 22, wherein the intermediate layer is formed as a pure carbon layer.

24. The method as claimed in claim 22, wherein the intermediate layer is applied in a thickness of 1 to 50 nm.

25. The method as claimed in claim 22, wherein the intermediate layer is pyrolytically applied.

26. The method as claimed in claim 22, wherein the first electrode layer is formed of phosphorus-doped polysilicon.

27. The method as claimed in claim 22, wherein the second electrode layer is formed of arsenic-doped polysilicon.

28. The method as claimed in claim 22, wherein
a trench is formed in a substrate,
one storage electrode formed as outer electrode in the substrate around the trench in a lower trench area,
the dielectric applied to the trench wall,
the trench being filled with the first electrode layer,
the first electrode layer removed from an upper trench area,
the dielectric exposed on the trench wall removed,
an insulation layer applied adjoining the dielectric on the trench wall in the upper trench area,
the intermediate layer being deposited,
the first electrode layer being covered completely and the insulation layer covered at least partially, and
the trench filled with the second electrode layer.

29. The method as claimed in claim 21, wherein
one storage electrode is formed with a metal layer, and
the intermediate layer which essentially consists of carbon is formed between the metal layer and a substrate.

30. The method as claimed in claim 29, wherein the intermediate layer is a pure carbon layer.

31. The method as claimed in claim 29, wherein the intermediate layer is 0.5 to 10 nm thick.

32. The method as claimed in claim 29, wherein the substrate is a silicon substrate.

33. The method as claimed in claim 21, wherein
one storage electrode is formed with a metal layer, and
the intermediate layer which essentially consists of carbon is formed between the metal layer and the dielectric.

34. The method as claimed in claim 33, wherein the intermediate layer is a pure carbon layer.

35. The method as claimed in claim 33, wherein the intermediate layer is 0.5 to 10 nm thick.

36. The method as claimed in claim 33, wherein the dielectric is a high-k dielectric.
